(19) United States
(12) Patent Application Publication
(10) Pub. No.: US 2026/0291198 A1
(43) Pub. Date: Sep. 24, 2026

(54) ELECTRICAL DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Hikari TERADA, Osaka (JP); Jo SUGIURA, Osaka (JP); Yusuke ISAJI, Osaka (JP); Hideyuki KUBOKI, Osaka (JP)

(21) Appl. No.: 19/476,174

(22) PCT Filed: Apr. 15, 2024
(86) PCT No.: PCT/JP2024/014964

§ 371 Date: Oct. 17, 2025

(30) Foreign Application Priority Data
Apr. 26, 2023 (JP) 2023-072159

(51) Int. Cl. H02G 5/02

(52) U.S. Cl. CPC H02G 5/02

(57) ABSTRACT

An electrical device includes a heat generation component, and a busbar connected to the heat generation component, and a holding member that holds the heat generation component and the busbar, wherein the busbar has a conductor portion CP, and an insulating member NP that has a radiation factor higher than that of the conductor portion CP and coats at least a part of an outer surface of the conductor portion CP.

### TECHNICAL FIELD

The present disclosure relates to an electrical device.

### BACKGROUND

Electrical devices installed in vehicles such as electric automobiles and hybrid automobiles include components such as relays that easily generate heat, and a configuration for dissipating the heat from the components is provided. As such an electrical device, the circuit assembly described in JP 2020-088087 A (Patent Document 1 below) is conventionally known. The circuit assembly described in Patent Document 1 includes a main relay serving as a heat generation component, a first busbar, a base member on which the main relay and the first busbar are mounted, an insulating plate stacked on the underside of the base member, and a metal heat sink plate stacked on the underside of the insulating plate. The first busbar includes a first electrical connection portion electrically connected to the main relay, a first heat-transfer connection portion, and a first bypass portion connecting the first electrical connection portion and the first heat-transfer connection portion. The first heat-transfer connection portion is in contact with the insulating plate through a first through hole provided in the base member. With this, the first heat-transfer connection portion is connected to a heat dissipation member via the insulating plate in a heat transfer manner. By providing the first bypass portion, the first heat-transfer connection portion can be provided at a position separated from the main relay, thereby allowing the heat of the main relay to be dissipated.

### PRIOR ART DOCUMENT

### Patent Document

Patent Document 1: JP 2020-088087 A

### SUMMARY OF THE INVENTION

### Problems to be Solved

In the above-described configuration, the insulating plate is provided to prevent the busbar from becoming conductive to the heat dissipation member. In addition, it is necessary to provide a separate upper case or the like to cover the busbar from above so that the upper surface of the busbar is not exposed to the outside. In this way, due to the necessity of providing a configuration for insulating the busbar in the circuit assembly, the number of components tends to be increased.

Also, in the above-described configuration, the first heat-transfer connection portion and the first bypass portion are provided on the first busbar to dissipate the heat from the main relay. Accordingly, there is concern that the first busbar will become larger.

### Means to Solve the Problem

An electrical device of the present disclosure includes a heat generation component, and a busbar connected to the heat generation component, and a holding member that holds the heat generation component and the busbar, wherein the busbar has a conductor portion, and an insulating member that has a radiation factor higher than that of the conductor portion and coats at least a part of an outer surface of the conductor portion.

### Effect of the Invention

According to the present disclosure, in the electrical device, the number of components used to insulate busbars can be reduced, and suppressing the size of the busbars as well as heat dissipation from the heat generation component can be realized.

### BRIEF DESCRIPTION OF THE DRAWINGS

FIG. 1 is a plan view showing an electrical device according to Embodiment 1.

FIG. 2 is a bottom view of the electrical device.

FIG. 3 is a perspective view of the electrical device mounted on a metal casing.

FIG. 4 is a perspective view of the electrical device mounted on the metal casing with a holding member omitted.

FIG. 5 is a schematic diagram showing a circuit configuration of the electrical device.

FIG. 6 is a perspective view of the holding member.

FIG. 7 is a perspective view of a first busbar.

FIG. 8 is a perspective view of the first busbar viewed in a direction different from in FIG. 7.

FIG. 9 is a perspective view of a second busbar.

FIG. 10 is a cross-sectional view taken along a line A-A in FIG. 1.

FIG. 11 is a perspective view of a fifth busbar.

FIG. 12 is a cross-sectional view taken along a line B-B in FIG. 2.

FIG. 13 is a perspective view of a sixth busbar.

FIG. 14 illustrates connection between the sixth busbar and a precharge resistor.

FIG. 15 is a perspective view of an eighth busbar.

FIG. 16 is a perspective view showing layout of the eighth busbar and a ninth busbar.

FIG. 17 illustrates a step of manufacturing the first busbar.

FIG. 18 is a plan view showing an electrical device according to Embodiment 2.

FIG. 19 is a bottom view of the electrical device.

FIG. 20 is a cross-sectional view taken along a line C-C in FIG. 18.

FIG. 21 is a perspective view of the electrical device mounted on the metal casing.

FIG. 22 is a perspective view of the electrical device mounted on the metal casing with a holding member omitted.

### DETAILED DESCRIPTION TO EXECUTE THE INVENTION

### Description of Embodiments of Present Disclosure

First, embodiments of the present disclosure will be listed and described.

[1] An electrical device of the present disclosure includes a heat generation component, a busbar connected to the heat generation component, and a holding member that holds the heat generation component and the busbar, wherein the busbar has a conductor portion, and an insulating member that has a radiation factor higher than that of the conductor portion and coats at least a part of an outer surface of the conductor portion.

With this configuration, since at least a part of the outer surface of the conductor portion of the busbar is coated with the insulating member, the insulation of the busbar from the outside can be easily guaranteed. Also, since the insulating member has a radiation factor higher than that of the conductor portion, heat transferred from the heat generation component to the busbar can be easily dissipated to the outside by radiation. In other words, heat dissipation from the heat generation component can be achieved easily. Accordingly, it is possible to dissipate heat from the heat generation component without increasing the size of the busbar.

[2] In the above-described feature [1], preferably, a part of the busbar is exposed to the outside.

With this configuration, it is possible to omit a member for externally covering the busbar.

[3] Preferably, the electrical device according to the above-described feature [1] or [2] is an electrical device mounted on a metal casing, and a part of the busbar is in contact with the metal casing.

With this configuration, heat transferred from the heat generation component to the busbar can be dissipated more easily.

### Detail of Embodiments of Present Disclosure

The following will describe embodiments of the present disclosure. The present disclosure is not limited to these examples, but is intended to include all changes within the meaning and scope equivalent to the claims. For convenience of description, some features may be exaggerated or simplified in the drawings. In addition, the dimensional ratios of each part may differ depending on the drawing. In the context of the present specification, the term “orthogonal” includes not only exactly orthogonal, but also approximately orthogonal to the extent that the functions and effects of the embodiments are achieved.

### Embodiment 1

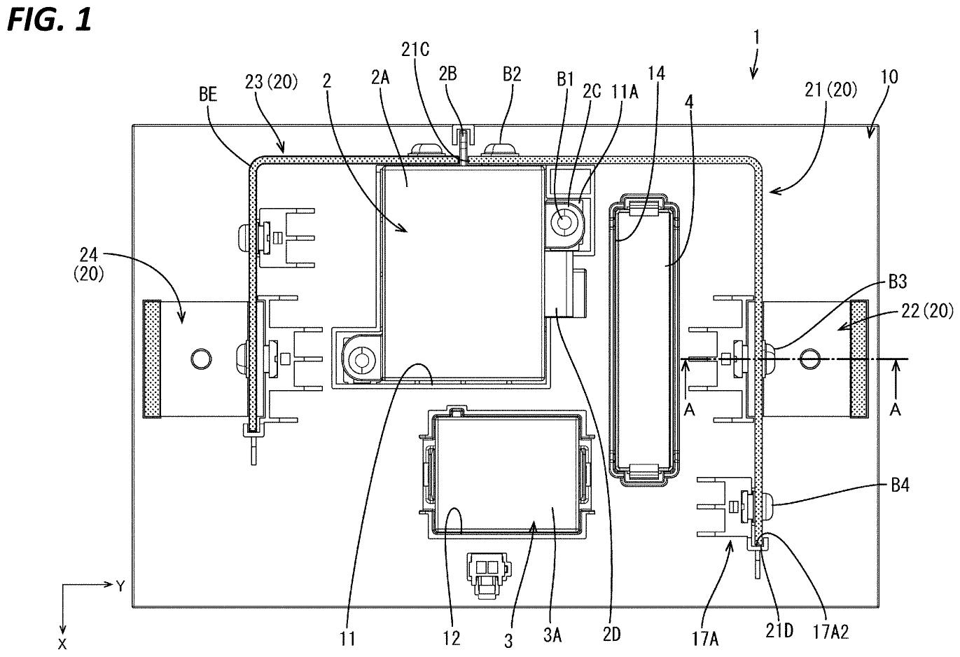

The following will describe Embodiment 1 of the present disclosure with reference to FIGS. 1 to 17. An electrical device 1 according to the present embodiment is installed, for example, in a vehicle such as an electric automobile or a hybrid automobile, and is arranged in a power supply path that connects a power source such as a battery and a load such as a motor. The electrical device 1 can be oriented in any direction, but in the following description, the direction indicated by the arrow Z is defined as upward, the direction indicated by the arrow X is defined as forward, and the direction indicated by the arrow Y is defined as leftward. Note that when there are multiple identical members, reference signs may be added to only some of the members, and reference signs for other members may be omitted.

### Electrical Device 1

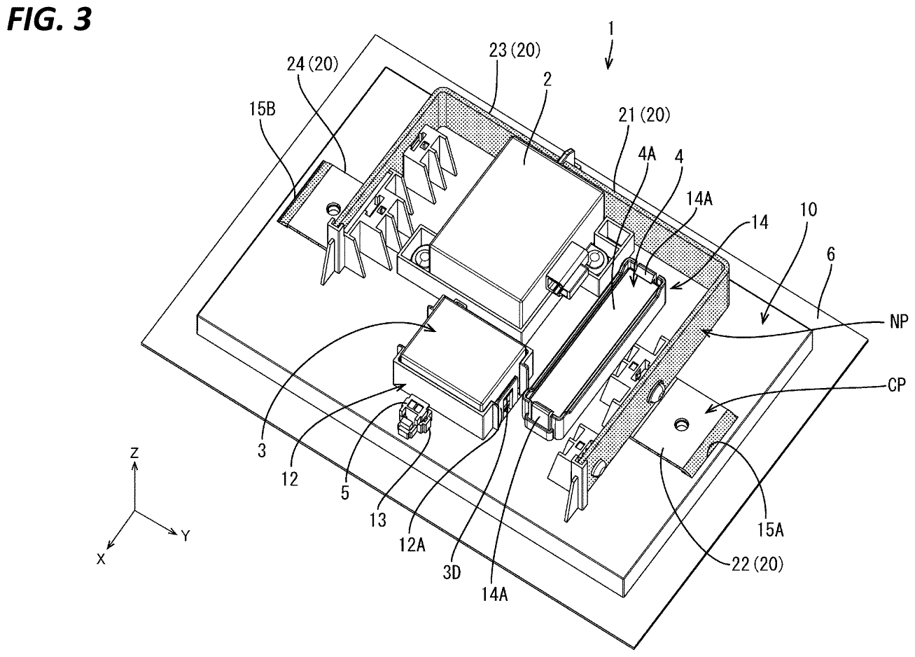

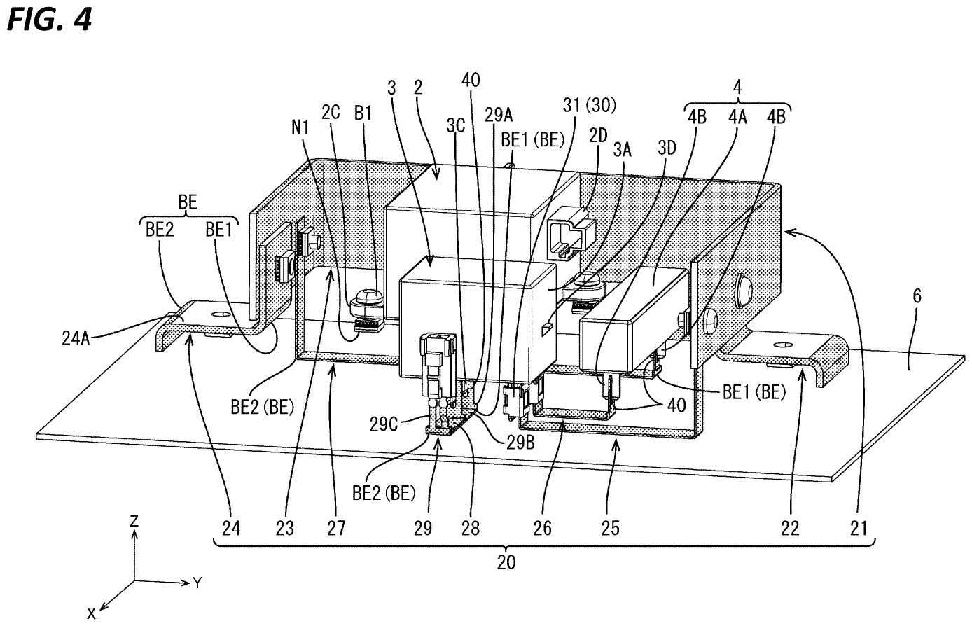

As shown in FIGS. 1 and 3, the electrical device 1 includes a main relay 2 (an example of a heat generation component), a precharge relay 3 (an example of the heat generation component), a precharge resistor 4 (an example of the heat generation component), a plurality of busbars 20, and a holding member 10. The holding member 10 holds the main relay 2, the precharge relay 3, the precharge resistor 4, and the plurality of busbars 20. As shown in FIG. 4, the plurality of busbars 20 include a first busbar 21, a second busbar 22, a third busbar 23, a fourth busbar 24, a fifth busbar 25, a sixth busbar 26, a seventh busbar 27, an eighth busbar 28, and a ninth busbar 29.

### Holding Member 10

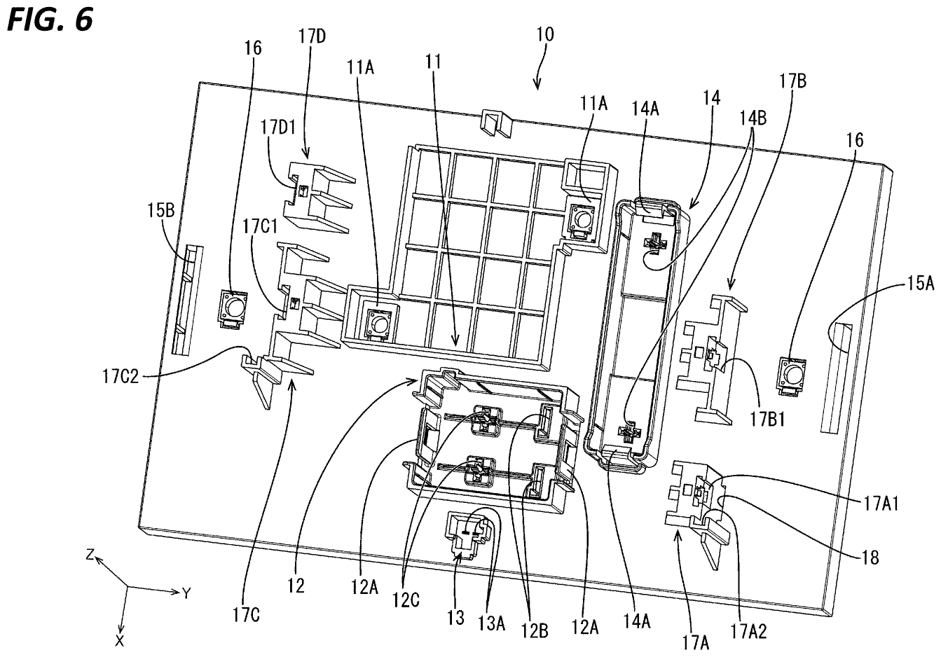

The holding member 10 is made of an insulating synthetic resin. As shown in FIG. 6, the holding member 10 as a whole is flat in shape in the up-down direction. A main relay housing 11 is formed in the center of the holding member 10 in the left-right direction. The main relay housing 11 is approximately frame-shaped. Nut mounting portions 11A, in which nuts N1 (see FIG. 4) are to be arranged, are formed respectively at the front right corner and left rear corner of the main relay housing 11. As shown in FIG. 1, the main relay 2 is housed in the main relay housing 11. A mounting bolt B1 is inserted into a mounting hole of a mounting piece 2C provided on the main relay 2 and is fastened to the nut N1 (see FIG. 4) of the nut mounting portion 11A of the main relay housing 11, thereby fixing the main relay 2 to the main relay housing 11.

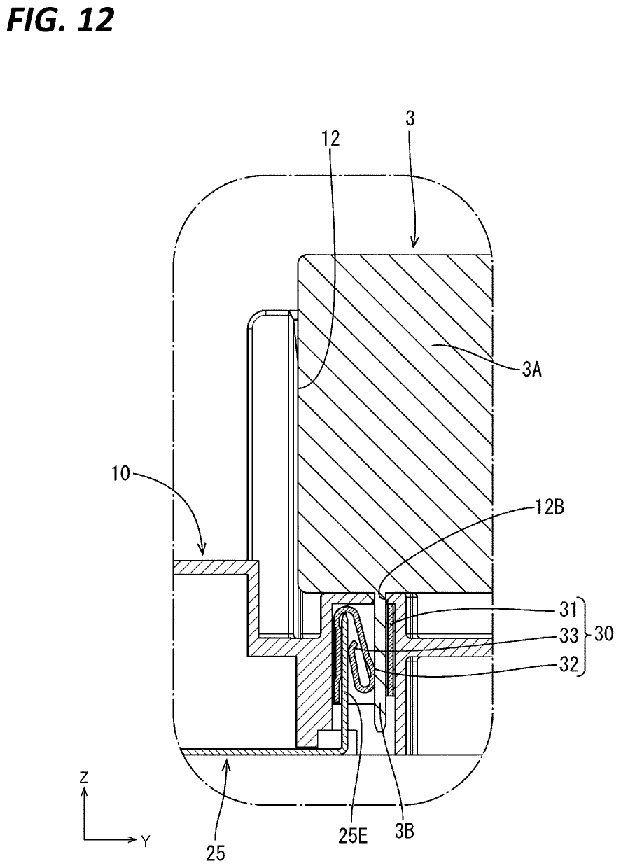

As shown in FIG. 6, the holding member 10 includes a precharge relay housing 12. The precharge relay housing 12 is arranged in front of the main relay housing 11. The precharge relay housing 12 is approximately frame-shaped. A lock receiving portion 12A, which is configured to be flexibly deformable, is formed on a side wall of the precharge relay housing 12. A first insertion hole 12B and a second insertion hole 12C are formed in the bottom of the precharge relay housing 12. As shown in FIG. 3, the precharge relay 3 is housed in the precharge relay housing 12, and the lock receiving portion 12A is designed to engage with a lock portion 3D of the precharge relay 3. As shown in FIG. 12, a first terminal portion 3B of the precharge relay 3 is inserted into the first insertion hole 12B. Although not shown in detail, a second terminal portion 3C of the precharge relay 3 is inserted into the second insertion hole 12C.

As shown in FIG. 6, the holding member 10 includes a connector fitting portion 13. The connector fitting portion 13 is arranged in front of the precharge relay housing 12. The connector fitting portion 13 has a substantially cylindrical shape with a bottom. Terminal holes 13A are formed in the bottom of the connector fitting portion 13. As shown in FIG. 3, a connector 5 is fitted to the connector fitting portion 13. Although not shown in detail, an end of the eighth busbar 28 and an end of the ninth busbar 29 are inserted into the terminal holes 13A.

As shown in FIG. 6, the holding member 10 includes a precharge resistor housing 14. The precharge resistor housing 14 is arranged to the left of the main relay housing 11 and the precharge relay housing 12. The precharge resistor housing 14 is elongated in the front-rear direction and is approximately frame-shaped. The precharge resistor housing 14 has, on its front and rear walls, engagement portions 14A, which are configured to be flexibly deformable. Third insertion holes 14B are formed in the bottom of the precharge resistor housing 14. As shown in FIG. 3, the precharge resistor housing 14 houses the precharge resistor 4, and the engagement portions 14A are engaged with a body portion 4A of the precharge resistor 4. Although not shown in detail, terminal portions 4B of the precharge resistor 4 are inserted into the respective third insertion holes 14B.

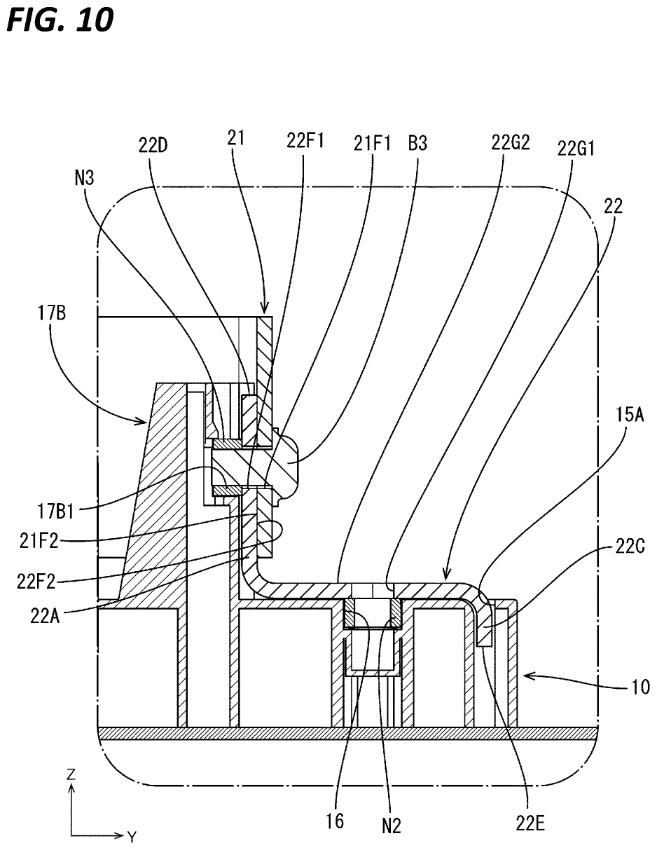

As shown in FIG. 6, busbar engagement holes 15A and 15B are formed at the left and right ends of the holding member 10. As shown in FIG. 3, the second busbar 22 is inserted into the left-side busbar engagement hole 15A. The fourth busbar 24 is inserted into the right-side busbar engagement hole 15B. The busbar engagement holes 15A and 15B allow the second busbar 22 and the fourth busbar 24 to be positioned with respect to the holding member 10. As shown in FIG. 6, the holding member 10 includes nut mounting portions 16 that are recessed from the upper surface. The nut mounting portions 16 are respectively located to the right of the busbar engagement hole 15A and to the left of the busbar engagement hole 15B. As shown in FIG. 10, a nut N2 is arranged in the nut mounting portion 16.

As shown in FIG. 6, the holding member 10 includes mounting columns 17A, 17B, 17C, and 17D, which extend upward from the upper surface of the holding member 10. The mounting column 17B is provided between the precharge resistor housing 14 and the nut mounting portion 16 located on the left side with respect to the left-right direction. The mounting column 17A is provided in front of the mounting column 17B. The mounting column 17C is provided between the main relay housing 11 and the nut mounting portion 16 located on the right side with respect to the left-right direction. The mounting column 17D is provided behind the mounting column 17C. The mounting columns 17A, 17B, 17C, and 17D respectively have nut mounting portions 17A1, 17B1, 17C1, and 17D1, in each of which a nut N3 (see FIG. 10) is to be arranged. A busbar insertion hole 18 is formed near each of the base of the mounting columns 17A and 17D of the holding member 10.

### Main Relay 2

The main relay 2 is a mechanical relay and has, inside thereof, a contact section and a coil section. As shown in FIG. 1, the main relay 2 has a body portion 2A in a rectangular parallelepiped shape, terminal portions (not shown) and a dividing wall 2B that are located on the rear side of the body portion 2A, the mounting piece 2C that protrudes from the body portion 2A, and a connector fitting portion 2D (see FIG. 4) on the left side of the body portion 2A. The terminal portions of the main relay 2 are each in the form of a nut to which a bolt B2 is fastened. The dividing wall 2B is placed between the two terminal portions. The dividing wall 2B is used to set the creepage distance between the two terminal portions. The mounting piece 2C has a mounting hole (not shown) through which the mounting bolt B1 is inserted. The main relay 2 is turned on and off by a signal externally transmitted via a connector (not shown) fitted to the connector fitting portion 2D.

### Precharge Relay 3 and Precharge Resistor 4

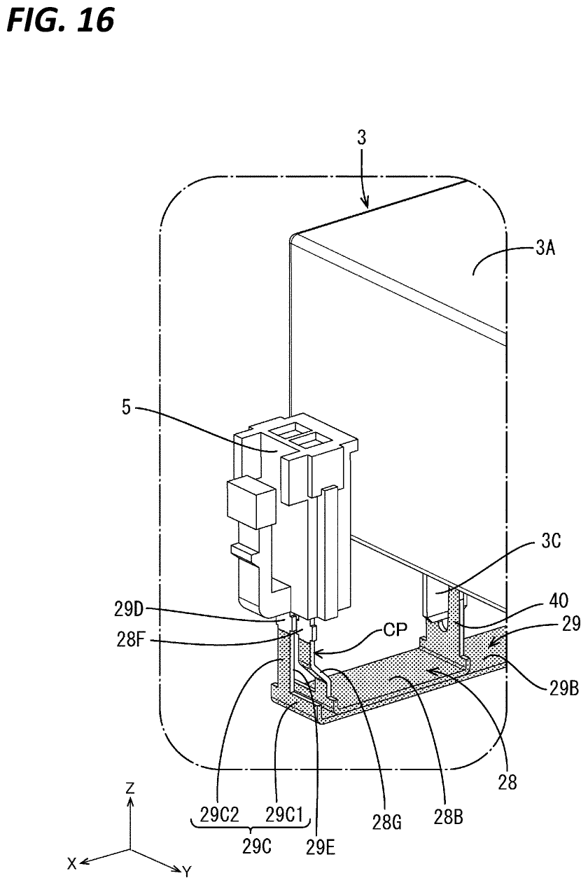

The precharge relay 3 is a mechanical relay that is smaller than the main relay 2, and has, inside thereof, a contact section and a coil section. The precharge relay 3 has a body portion 3A in a rectangular parallelepiped shape, a first terminal portion 3B (see FIG. 12) and a second terminal portion 3C (see FIG. 16) that protrude from the lower surface of the body portion 3A, and a lock portion 3D (see FIG. 4) that protrudes from the body portion 3A. Here, the first terminal portion 3B and the second terminal portion 3C are examples of terminal portions. As shown in FIG. 4, the precharge resistor 4 has a body portion 4A in a rectangular parallelepiped shape, and a terminal portion 4B that protrudes from the lower surface of the body portion 4A. The precharge relay 3 and the precharge resistor 4 are constituent components of a precharge circuit.

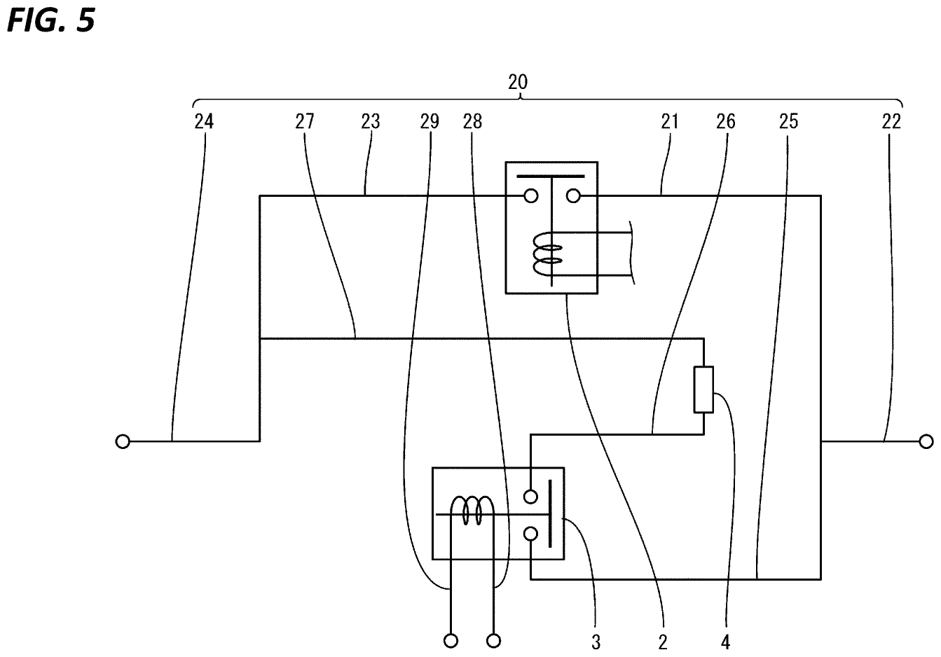

FIG. 5 is a schematic diagram of the circuit configuration of the electrical device 1, and shows electrical connection between the components and the busbars 20. The precharge circuit is connected in parallel to the main relay 2. The precharge relay 3 is turned on and off by a signal externally transmitted via the connector 5 (see FIG. 3) fitted to the connector fitting portion 13. The second terminal portion 3C is connected to this connector 5 via the eighth busbar 28 and the ninth busbar 29 (see FIG. 16). The precharge relay 3 is turned on and then the main relay 2 is turned on, thereby suppressing an inrush current from flowing into the main relay 2.

### Busbar 20

The plurality of busbars 20 have the following features in common. As shown in FIG. 4, each of the busbars 20 is connected to any of components (the main relay 2, the precharge relay 3, and the precharge resistor 4) that generate heat upon being energized, directly or indirectly via another busbar 20. This allows heat to be transferred from the heat generation components to the busbars 20.

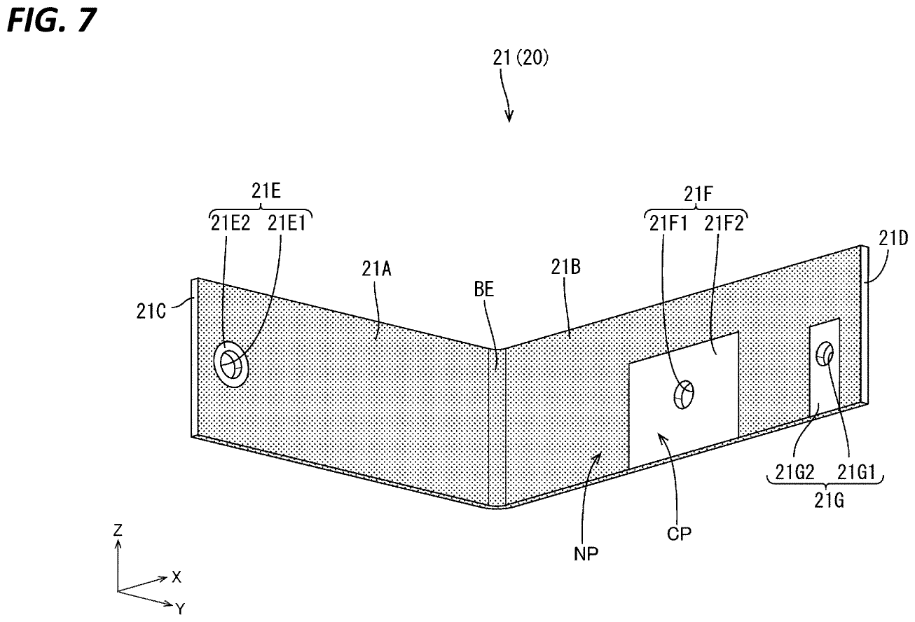

Each busbar 20 has a conductor portion CP and an insulating member NP that coats at least a part of the outer surface of the conductor portion CP (see, for example, the first busbar 21 in FIG. 7). The insulating member NP has a film thickness (e.g., several tens of micrometers) that is sufficient to ensure insulation with the conductor portion CP connected to a battery or the like even when something comes into contact with the surface of the insulating member NP. In the drawing, the insulating member NP corresponds to the hatched area. The conductor portion CP is made of a metal such as copper, a copper alloy, aluminum, and an aluminum alloy, and has a plate shape. The insulating member NP has a radiation factor higher than that of the conductor portion CP. For example, insulating resin materials such as polyimide, fluorine resins, and epoxy resins can be used as the insulating member NP.

The insulating member NP preferably covers the portion of the outer surface of the conductor portion CP that is not hidden by another member (such as the holding member 10). This can suppress contact with the conductor portion CP from the outside.

Each busbar 20 is short in the short side direction and has a shape such that it is bent in at least one position. Bent edges BE of the busbars 20 all extend in the short side direction. These are the features common to the plurality of busbars 20, and the configurations of the busbars 20 are described in detail below. Note that, in the following description, the same reference signs are added to the conductor portions CP, the insulating members NP, and the bent edges BE. However, the busbars 20 may have different shapes of the conductor portion CP, different extents to which the insulating member NP is formed with respect to the conductor portion CP, and different numbers of bent edges BE.

### First Busbar 21

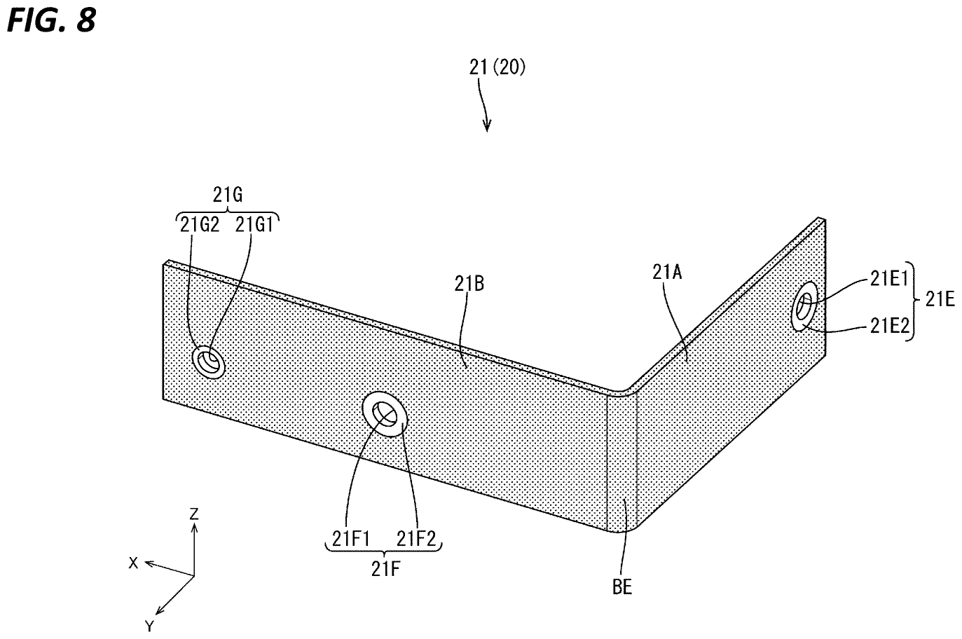

As shown in FIG. 1, the first busbar 21 has a substantially L-shape in a plan view. As shown in FIGS. 7 and 8, the first busbar 21 has a first portion 21A and a second portion 21B bent with respect to the first portion 21A. The first portion 21A extends in the left-right direction. The second portion 21B extends in the front-rear direction. The bent edge BE is formed between the left end of the first portion 21A and the rear end of the second portion 21B. The bent edge BE of the first busbar 21 extends in the short side direction (up-down direction) of the first busbar 21.

As shown in FIG. 7, the outer surface of the conductor portion CP of the first busbar 21 is coated with the insulating member NP, except for two cut surfaces 21C and 21D and three connection portions 21E, 21F, and 21G. In other words, the conductor portion CP is exposed to the outside at the cut surfaces 21C and 21D and the connection portions 21E, 21F, and 21G. The cut surfaces 21C and 21D are respectively located on the right end face of the first portion 21A and the front end face of the second portion 21B. As shown in FIG. 1, the cut surface 21C is located in close proximity to the dividing wall 2B of the main relay 2 while facing the dividing wall 2B. The cut surface 21D is received in a groove 17A2 formed in the mounting column 17A of the holding member 10. This prevents external contact with the cut surfaces 21C and 21D.

As shown in FIG. 7, the first portion 21A has the connection portion 21E at its right end. The connection portion 21E has a through hole 21E1 that passes through the conductor portion CP in the front-rear direction, and a connection surface 21E2 formed on the hole edge portion of the through hole 21E1. Although not shown in detail, by inserting the bolt B2 (see FIG. 1) through the through hole 21E1 and fastening this bolt B2 to the terminal portion of the main relay 2, the connection surface 21E2 and the terminal portion of the main relay 2 come into contact. This electrically connects the main relay 2 and the first busbar 21. The bolt B2 has the same configuration as that of a later-described bolt B3.

As shown in FIG. 7, the second portion 21B has the connection portion 21F in the center thereof in the front-rear direction. The connection portion 21F is a portion connected to the later-described second busbar 22. The connection portion 21F has a through hole 21F1 that passes through the conductor portion CP in the left-right direction and a connection surface 21F2 formed on the hole edge portion of the through hole 21F1. The right-side connection surface 21F2 provided on the connection portion 21F has a rectangular shape that corresponds to the size of the later-described second busbar 22.

The second portion 21B has the connection portion 21G at its front end. The connection portion 21G is a portion connected to the later-described fifth busbar 25. The connection portion 21G is configured in substantially the same manner as the connection portion 21F, and has a through hole 21G1 and a connection surface 21G2. The right-side connection surface 21G2 provided on the connection portion 21G has a rectangular shape that corresponds to the size of the fifth busbar 25.

### Second Busbar 22

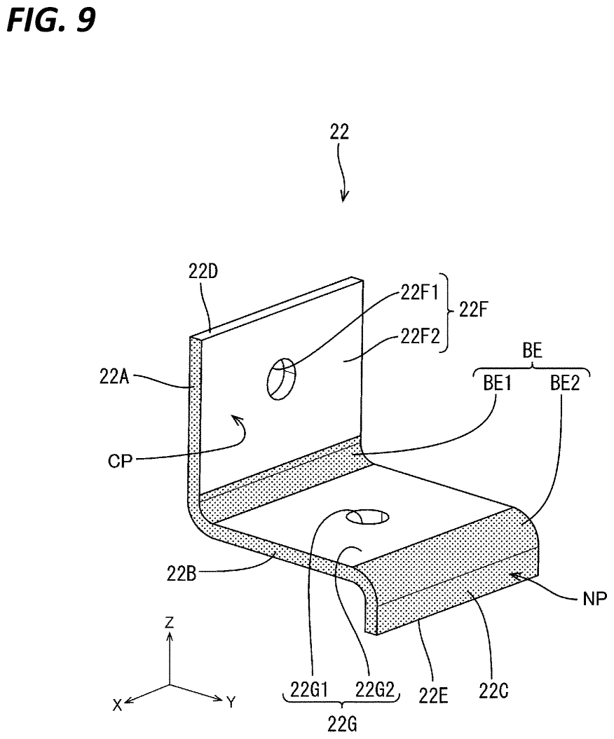

As shown in FIG. 10, the second busbar 22 is crank-shaped when viewed in the front-rear direction. As shown in FIG. 9, the second busbar 22 has a first portion 22A, a second portion 22B bent with respect to the first portion 22A, and a third portion 22C bent with respect to the second portion 22B. The first portion 22A extends in the up-down direction. The second portion 22B extends in the left-right direction. The third portion 22C extends in the up-down direction. The bent edge BE of the second busbar 22 includes a first bent edge BE1 and a second bent edge BE2. The first bent edge BE1 is formed between the lower end of the first portion 22A and the right end of the second portion 22B. The second bent edge BE2 is formed between the left end of the second portion 22B and the upper end of the third portion 22C. The bent edges BE (first bent edge BE1 and second bent edge BE2) of the second busbar 22 extend in the short side direction of the second busbar 22 (in the front-rear direction).

The outer surface of the conductor portion CP of the second busbar 22 is coated with the insulating member NP, except for two cut surfaces 22D and 22E and two connection portions 22F and 22G. In other words, the conductor portion CP is exposed to the outside at the cut surfaces 22D and 22E and the connection portions 22F and 22G. The cut surfaces 22D and 22E are respectively located on the upper end face of the first portion 22A and the lower end face of the third portion 22C. As shown in FIG. 10, the third portion 22C is inserted into the busbar engagement hole 15A of the holding member 10. With this, the cut surface 22E on the lower end face of the third portion 22C is located inside the busbar engagement hole 15A. Also, the first portion 22A is connected to the first busbar 21, so that the cut surface 22D on the upper end face of the first portion 22A is located below the upper end face of the first busbar 21 and the upper end of the mounting column 17B. Accordingly, the cut surfaces 22D and 22E are located at positions where external contact with the cut surfaces 22D and 22E is difficult.

As shown in FIG. 9, the first portion 22A has the connection portion 22F. The connection portion 22F has a through hole 22F1 that passes through the conductor portion CP in the left-right direction and a connection surface 22F2 formed on the hole edge portion of the through hole 22F1. As shown in FIG. 10, by inserting the bolt B3 through the through hole 22F1 and the through hole 21F1 of the first busbar 21 and fastening this bolt B3 to the nut N3 of the nut mounting portion 17B1 of the mounting column 17B, the connection surface 22F2 and the connection surface 21F2 of the first busbar 21 come into contact. With this, the second busbar 22 and the first busbar 21 are electrically connected to each other.

The bolt B3 has a head that is large enough to hide the connection surface 21F2 (see FIG. 8) that is in contact with the bolt B3. Note that the head refers to a portion that is formed at the end of the shaft inserted into the through holes 21F1 and 22F1, and has a diameter increasing from the shaft portion. The bolt B3 has a head whose surface is at least insulated. For example, the portion of the bolt B3 other than the surface of the head may be made of metal. Also, the bolt B3 as a whole may be made of an insulating resin. This prevents the bolt B3 from being electrically connected to the conductor portions CP of the first and second busbars 21 and 22 when the head of the bolt B3 is externally contacted.

As shown in FIG. 9, the second portion 22B has the connection portion 22G. The connection portion 22G has a through hole 22G1 that passes through the conductor portion CP in the up-down direction and a connection surface 22G2 formed on the hole edge portion of the through hole 22G1. The connection portion 22G is a portion to be connected to a first external connection busbar (not shown). The first external connection busbar is electrically connected to a load such as a motor, for example. As shown in FIG. 10, by inserting a bolt (not shown) through the through hole 22G1 and the through hole of the first external connection busbar (not shown) and fastening this bolt to the nut N2 of the nut mounting portion 16, the connection surface 22G2 and the first external connection busbar come into contact. With this, the second busbar 22 and the first external connection busbar are electrically connected to each other.

### Third Busbar 23

As shown in FIG. 1, the third busbar 23 has a substantially L-shape in a plan view, and is configured in substantially the same manner as the first busbar 21. The bent edge BE of the third busbar 23 extends in the short side direction (up-down direction) of the third busbar 23. Although not shown in detail, the third busbar 23 has a connection portion connected to the terminal portion of the main relay 2, a connection portion connected to the fourth busbar 24, and a connection portion connected to the seventh busbar 27 (see FIG. 4).

### Fourth Busbar 24

As shown in FIG. 4, the fourth busbar 24 is crank-shaped when viewed in the front-rear direction, and is configured in substantially the same manner as the second busbar 22. The bent edges BE of the fourth busbar 24 include a first bent edge BE1 and a second bent edge BE2, and extend in the short side direction of the fourth busbar 24 (in the front-rear direction). The fourth busbar 24 has a connection portion (not shown) connected to the third busbar 23 and a connection portion 24A connected to a second external connection busbar (not shown). The second external connection busbar is electrically connected to a power source such as a battery, for example.

### Fifth Busbar 25

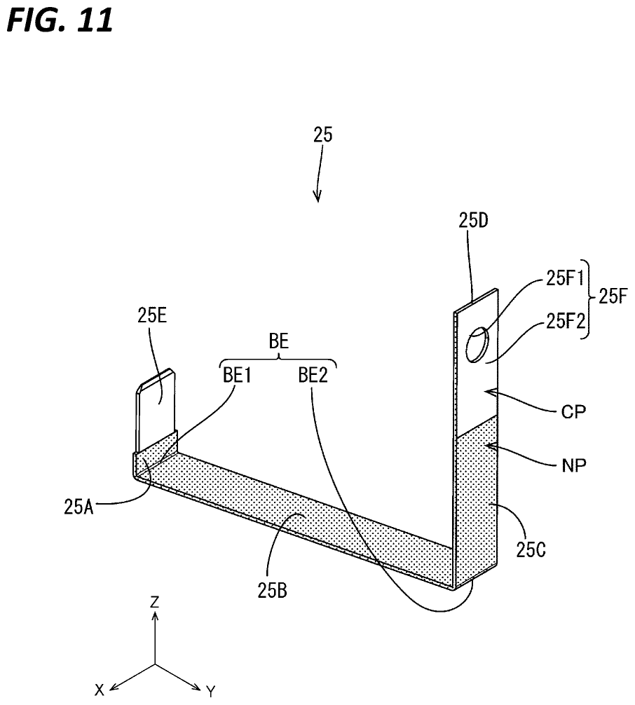

As shown in FIG. 11, the fifth busbar 25 has an angular and substantially U-shape when viewed in the front-rear direction. The fifth busbar 25 has a first portion 25A, a second portion 25B bent with respect to the first portion 25A, and a third portion 25C bent with respect to the second portion 25B. The first portion 25A extends in the up-down direction. The second portion 25B extends in the left-right direction. The third portion 25C extends in the up-down direction. The bent edges BE of the fifth busbar 25 includes a first bent edge BE1 and a second bent edge BE2. The first bent edge BE1 is formed between the lower end of the first portion 25A and the right end of the second portion 25B. The second bent edge BE2 is formed between the left end of the second portion 25B and the lower end of the third portion 25C. The bent edges BE (first bent edge BE1 and second bent edge BE2) of the fifth busbar 25 extend in the short side direction of the fifth busbar 25 (in the front-rear direction).

The outer surface of the conductor portion CP of the fifth busbar 25 is coated with the insulating member NP, except for one cut surface 25D and two connection portions 25E and 25F. In other words, the conductor portion CP is exposed to the outside at the cut surface 25D and the connection portions 25E and 25F. The cut surface 25D is located on the upper end face of the third portion 25C. The third portion 25C is connected to the first busbar 21. Although not shown in detail, the cut surface 25D is located below the upper end face of the first busbar 21 and the upper end of the mounting column 17A. Accordingly, the cut surface 25D is located at a position where external contact with the cut surface 25D is difficult. The first portion 25A has a tab-shaped connection portion 25E at its upper end. The conductor portion CP is exposed from the entire outer surface of the connection portion 25E. The connection portion 25E is electrically connected to the first terminal portion 3B of the precharge relay 3 via an intermediate terminal 30, which will be described below.

### Intermediate Terminal 30

As shown in FIG. 12, the intermediate terminal 30 includes a tubular connection portion 31 (see FIG. 4), a first contact portion 32, and a second contact portion 33. The tubular connection portion 31 is square tubular, and is open upward and downward. The first contact portion 32 and the second contact portion 33 are arranged inside the tubular connection portion 31. The first contact portion 32 is defined as an elastic piece that extends obliquely downward from the upper end of the right wall of the tubular connection portion 31. The second contact portion 33 is defined as an elastic piece that extends obliquely upward from the lower end of the first contact portion 32. The second contact portion 33 is arranged between the first contact portion 32 and the right wall of the tubular connection portion 31.

The first terminal portion 3B of the precharge relay 3 is inserted into the tubular connection portion 31 from above the tubular connection portion 31 to come into contact with the first contact portion 32. The connection portion 25E of the fifth busbar 25 is inserted into the tubular connection portion 31 from below the tubular connection portion 31 to come into contact with the second contact portion 33. With this, the first terminal portion 3B of the precharge relay 3 and the fifth busbar 25 are electrically connected to each other.

As shown in FIG. 11, the connection portion 25F of the third portion 25C has a through hole 25F1 passing through the conductor portion CP in the left-right direction, and a connection surface 25F2 formed on the hole edge portion of the through hole 25F1. The left-side connection surface 25F2 provided on the connection portion 25F has a rectangular shape that corresponds to the size of the first busbar 21. The third portion 25C is inserted into the busbar insertion hole 18 (see FIG. 6) of the holding member 10 and is placed while overlapping the first busbar 21. Also, the fifth busbar 25 and the first busbar 21 are electrically connected to each other in the same manner as the connection between the second busbar 22 and the first busbar 21 (see FIG. 10). In other words, by inserting the bolt B4 (see FIG. 1) through the through hole 25F1 and the through hole 21G1 of the first busbar 21 and fastening this bolt B4 to the nut N3 of the nut mounting portion 17A1 of the mounting column 17A, the connection surface 25F2 and the connection surface 21G2 of the first busbar 21 come into contact. The bolt B4 is configured in the same manner as the above-described bolt B3.

### Sixth Busbar 26

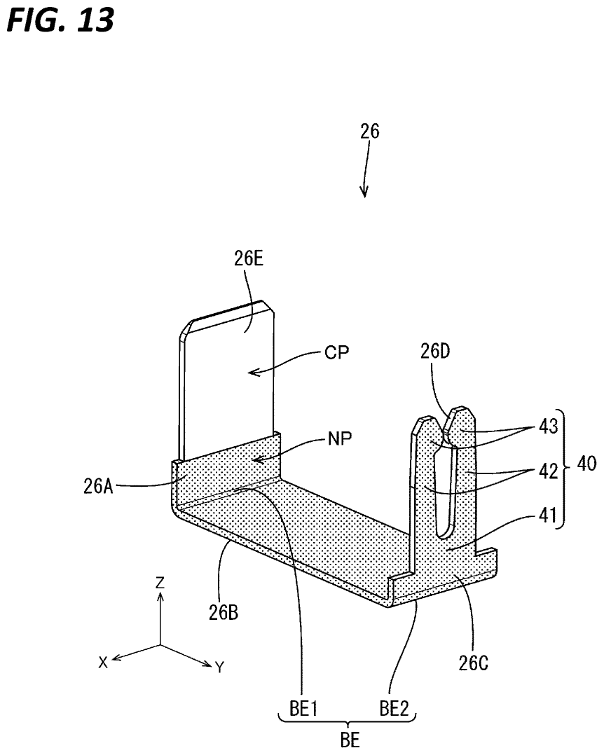

As shown in FIG. 13, the sixth busbar 26 has an angular and substantially U-shape when viewed in the front-rear direction. The sixth busbar 26 has a first portion 26A, a second portion 26B bent with respect to the first portion 26A, and a third portion 26C bent with respect to the second portion 26B. The first portion 26A extends in the up-down direction. The second portion 26B extends in the left-right direction. The third portion 26C extends in the up-down direction. The bent edges BE of the sixth busbar 26 include a first bent edge BE1 and a second bent edge BE2. The first bent edge BE1 is formed between the lower end of the first portion 26A and the right end of the second portion 26B. The second bent edge BE2 is formed between the left end of the second portion 26B and the lower end of the third portion 26C. The bent edges BE (first bent edge BE1 and second bent edge BE2) of the sixth busbar 26 extend in the short side direction of the sixth busbar 26 (in the front-rear direction).

The outer surface of the conductor portion CP of the sixth busbar 26 is coated with the insulating member NP, except for a cut surface 26D and a connection portion 26E. In other words, the conductor portion CP is exposed to the outside at the cut surface 26D and the connection portion 26E. The cut surface 26D includes an end surface of a tuning fork terminal 40, which will be described below. The first portion 26A has a tab-shaped connection portion 26E at its upper end. The conductor portion CP is exposed from the entire outer surface of the connection portion 26E. The connection portion 26E is electrically connected to the first terminal portion 3B of the precharge relay 3 via the intermediate terminal 30 (see FIG. 4).

### Tuning Fork Terminal 40

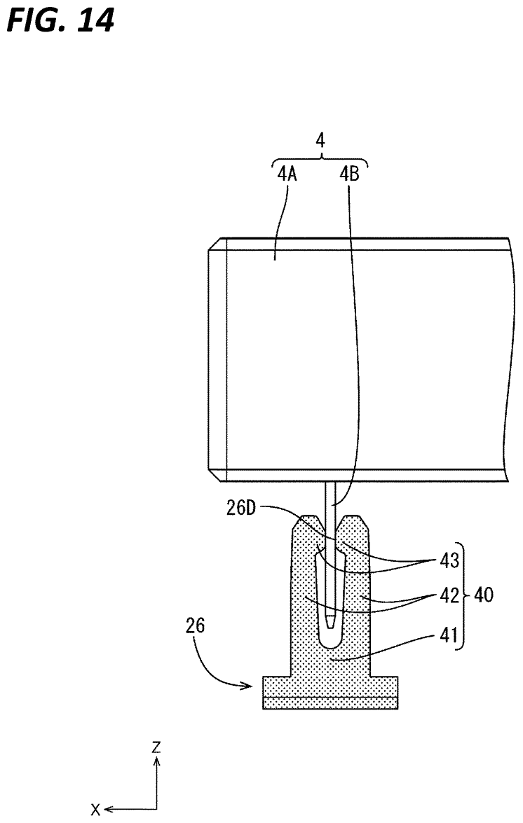

The third portion 26C includes the tuning fork terminal 40. The tuning fork terminal 40 has a substantially U-shape when viewed in the left-right direction. The tuning fork terminal 40 includes a base 41, and a pair of pinching pieces 42 extending upward from two ends of the base 41 in the front-rear direction. Protrusions 43 are respectively formed at the leading ends (upper ends) of the pinching pieces 42. Each of the protrusions 43 protrudes from the corresponding pinching piece 42 in a direction of narrowing the space between the pair of pinching pieces 42. The left and right sides of the tuning fork terminal 40 are coated with the insulating member NP. On the other hand, the cut surface 26D created when forming the tuning fork terminal 40 is not coated with the insulating member NP and serves as a portion where the conductor portion CP is exposed. When the terminal portion 4B of the precharge resistor 4 is inserted between the pair of pinching pieces 42 of the tuning fork terminal 40, the terminal portion 4B of the precharge resistor 4 is pinched by the pair of protrusions 43, as shown in FIG. 14. Then, the cut surface 26D provided on the protrusions 43 and the terminal portion 4B of the precharge resistor 4 come into contact. As a result, the sixth busbar 26 and the precharge resistor 4 are electrically connected to each other. By providing the tuning fork terminal 40 in this way, it is possible to easily connect the end of the sixth busbar 26 and the terminal portion 4B of the precharge resistor 4, whose thicknesses directions are orthogonal to each other. In addition, since the cut surface 26D of the third portion 26C is arranged inside the holding member 10, it is possible to prevent external contact with the conductor portion CP of the sixth busbar 26.

### Seventh Busbar 27

As shown in FIG. 4, the seventh busbar 27 has an angular and substantially U-shape when viewed in the front-rear direction. The bent edges BE of the seventh busbar 27 include a first bent edge BE1 and a second bent edge BE2, and extend in the short side direction of the seventh busbar 27 (in the front-rear direction). The seventh busbar 27 is configured in substantially the same manner as the connection portion 25F of the fifth busbar 25, and includes a connection portion (not shown) connected to the third busbar 23, and a tuning fork terminal 40 connected to the terminal portion 4B of the precharge resistor 4.

### Eighth Busbar 28

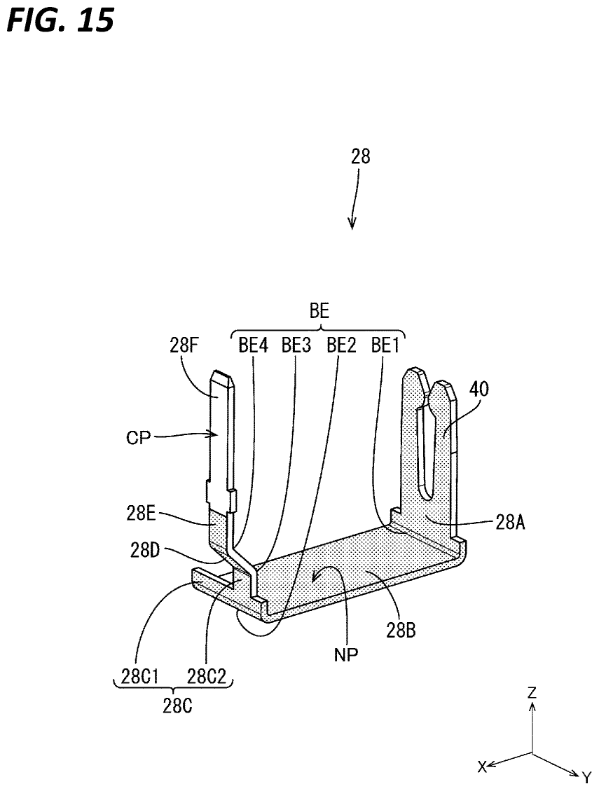

As shown in FIG. 15, the eighth busbar 28 has a first portion 28A, a second portion 28B bent with respect to the first portion 28A, a third portion 28C bent with respect to the second portion 28B, a fourth portion 28D bent with respect to the third portion 28C, and a fifth portion 28E bent with respect to the fourth portion 28D. The first portion 28A extends in the up-down direction. The second portion 28B extends in the front-rear direction. The third portion 28C extends in the up-down direction. The fourth portion 28D extends obliquely upward and forward from the third portion 28C. The fifth portion 28E extends in the up-down direction. The third portion 28C has a wide portion 28C1 connected to the second portion 28B and a narrow portion 28C2 extending upward from the wide portion 28C1 and is narrower than the wide portion 28C1. The narrow portion 28C2 is located to the left of the center of the wide portion 28C1 in the left-right direction. The narrow portion 28C2 is connected to the fourth portion 28D. The fourth portion 28D and the fifth portion 28E have substantially the same width dimension (dimension in the left-right direction) as the narrow portion 28C2.

The bent edges BE of the eighth busbar 28 include a first bent edge BE1, a second bent edge BE2, a third bent edge BE3, and a fourth bent edge BE4. The first bent edge BE1 is formed between the lower end of the first portion 28A and the rear end of the second portion 28B. The second bent edge BE2 is formed between the front end of the second portion 28B and the lower end of the third portion 28C (wide portion 28C1). The third bent edge BE3 is formed between the upper end of the third portion 28C (narrow portion 28C2) and the lower end of the fourth portion 28D. The fourth bent edge BE4 is formed between the upper end of the fourth portion 28D and the lower end of the fifth portion 28E. The bent edges BE (first bent edge BE1, second bent edge BE2, third bent edge BE3, and fourth bent edge BE4) of the eighth busbar 28 extend in the short side direction of the eighth busbar 28 (in the left-right direction).

The first portion 28A includes a tuning fork terminal 40. The fifth portion 28E has a tab-shaped connection portion 28F at its upper end. The conductor portion CP is exposed from the entire outer surface of the connection portion 28F. As shown in FIG. 16, the tuning fork terminal 40 is connected to the second terminal portion 3C of the precharge relay 3. The connection portion 28F is inserted into the terminal hole 13A in the connector fitting portion 13 of the holding member 10, and is arranged inside the connector fitting portion 13 (see FIG. 6). The connection portion 28F is connected to the connector 5 fitted to the connector fitting portion 13.

### Ninth Busbar 29

The ninth busbar 29 is configured in substantially the same manner as the eighth busbar 28. As shown in FIG. 4, the ninth busbar 29 has a first portion 29A, a second portion 29B bent with respect to the first portion 29A, and a third portion 29C bent with respect to the second portion 29B. The first portion 29A extends in the up-down direction, and includes a tuning fork terminal 40. The second portion 29B extends in the front-rear direction. The third portion 29C extends in the up-down direction. The bent edges BE of the ninth busbar 29 only include a first bent edge BE1 and a second bent edge BE2. The first bent edge BE1 is formed between the lower end of the first portion 29A and the rear end of the second portion 29B. The second bent edge BE2 is formed between the front end of the second portion 29B and the lower end of the third portion 29C.

As shown in FIG. 16, the second portion 29B is longer than the second portion 28B of the eighth busbar 28 in the front-rear direction. The third portion 29C has a wide portion 29C1 connected to the second portion 29B, and a narrow portion 29C2 that extends upward from the wide portion 29C1 and is narrower than the wide portion 29C1. The narrow portion 29C2 is located to the right of the center of the wide portion 29C1 in the left-right direction. A tab-shaped connection portion 29D is formed at the upper end of the narrow portion 29C2. The connection portion 29D is designed to be connected to the connector 5.

The second portion 28B of the eighth busbar 28 is placed on top of the second portion 29B of the ninth busbar 29. The connection portion 28F of the eighth busbar 28 and the connection portion 29D of the ninth busbar 29 are arranged side by side in the left-right direction. Cut surfaces 28G and 29E that respectively appear due to the formation of the connection portions 28F and 29D expose the conductor portions CP, but these cut surfaces 28G and 29E are arranged separated from each other by a spatial distance that enables insulation to be maintained. By placing the eighth busbar 28 and the ninth busbar 29 on top of each other in this manner, the space for the eighth and ninth busbars 28 and 29 can be downsized.

In the present embodiment, as shown in FIG. 3, at least portions of the first busbar 21, the second busbar 22, the third busbar 23, and the fourth busbar 24 are exposed to the outside on the top side of the holding member 10. Each busbar 20 is provided with the insulating member NP so that, in the electrical device 1, the busbar 20 is insulated from the outside even when a part of the busbar 20 is exposed to the outside. Therefore, the electrical device 1 does not need to be provided with an insulating member that covers the entire busbar 20, making it possible to reduce the number of components of the electrical device 1. In addition, since, in the electrical device 1, the entire busbar 20 is not covered, the heat accumulation in the busbars 20 of the electrical device 1 can be mitigated. Furthermore, the portions of the busbars 20 that are exposed to the outside are each the insulating member NP, which has a radiation factor higher than that of the conductor portion CP, so the heat of the busbars 20 can be efficiently radiated to the outside. Therefore, the heat dissipation of the busbars 20 can be improved.

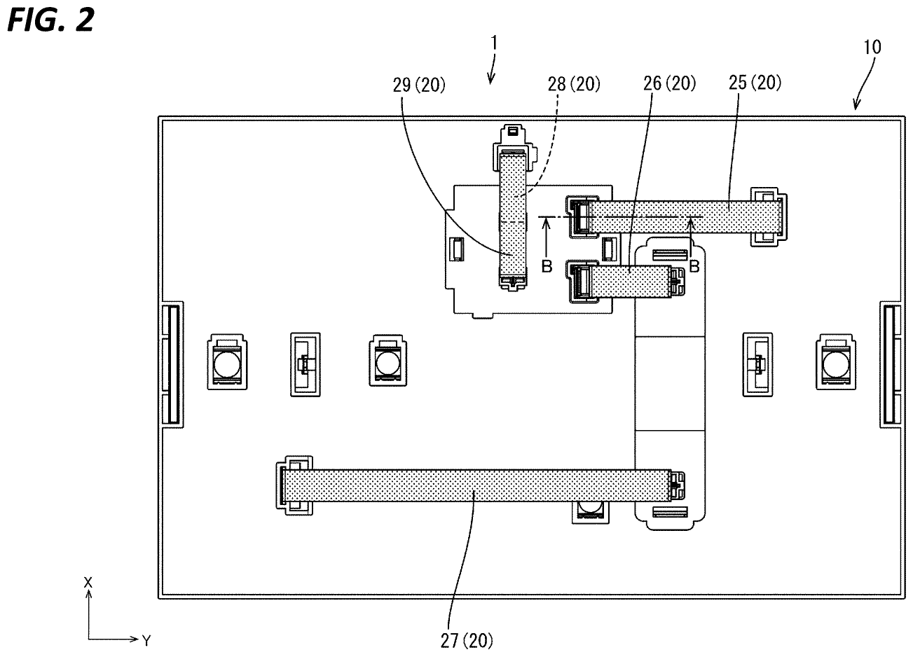

The electrical device 1 of the present embodiment is mounted on a metal casing 6. Note that only the portion of the metal casing 6 where the electrical device 1 is installed is shown in the drawings. The metal casing 6 may, for example, internally house a battery. As shown in FIG. 2, in the electrical device 1, the fifth busbar 25, the sixth busbar 26, the seventh busbar 27, the eighth busbar 28, and the ninth busbar 29 are mounted on the underside of the holding member 10. When the electrical device 1 is mounted on the metal casing 6, the fifth busbar 25, the sixth busbar 26, the seventh busbar 27, the eighth busbar 28, and the ninth busbar 29 are not exposed to the outside and are in contact with the metal casing 6 inside the holding member 10 (see FIGS. 3 and 4). Note that the eighth busbar 28 is connected to the metal casing 6 via the ninth busbar 29. The portions of the busbars 20 that are in contact with the metal casing 6 are the insulating members NP, and thus conduction between the busbars 20 and the metal casing 6 is prevented. The contact of the busbars 20 with the metal casing 6 allows the heat of the busbars 20 to be transferred to the metal casing 6. Thus, the heat dissipation properties of the busbars 20 can be improved.

### Method for Manufacturing Electrical Device 1

The configuration of the electrical device 1 has been described so far, and the following will describe an example of a method for manufacturing the electrical device 1. The method for manufacturing the electrical device 1 includes a step of manufacturing the busbar 20, a step of manufacturing the holding member 10, and a step of assembling components.

### Step of Manufacturing Busbar 20

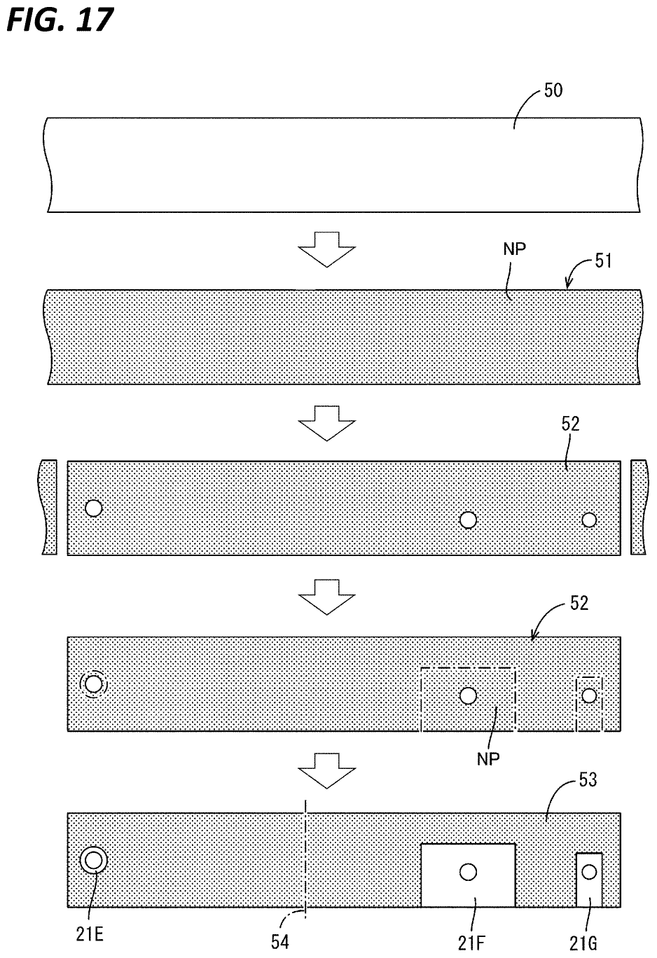

Hereinafter, an example of the step of manufacturing the busbar 20 will be described below with reference to FIG. 17. The following will describe the manufacturing step (manufacturing method) for manufacturing the first busbar 21, which is a representative example of the busbar 20. First, a strip-shaped metal plate material 50 extending in one direction is prepared (first step). This metal plate material 50 serves as the conductor portion CP of the busbar 20. The short side direction of the metal plate material 50 (up-down direction of the illustration in FIG. 17) corresponds to the short side direction of the busbar 20.

Next, the outer surface of the metal plate material 50 is coated with the insulating member NP to obtain a coated plate material 51 (second step). Since the metal plate material 50 is strip-shaped extending in one direction, an extruder can be used to form the insulating member NP on the outer surface of the metal plate material 50 in the second step. That is, while the extruder is used to feed the metal plate material 50 in its extending direction (long side direction), the insulating member NP can be attached to the outer surface of the metal plate material 50. The short side direction of the metal plate material 50 is a direction that is orthogonal to the direction in which the metal plate material 50 is fed by the extruder. By using an extruder, the work efficiency of the second step can be increased and the manufacturing cost of the busbar 20 can be reduced.

The coated plate material 51 is cut and holes are formed, so that a first molded body 52 is obtained (third step). When manufacturing the first busbar 21, the cutting line is straight, but the cutting line may be changed as appropriate according to the shape of the busbar 20 to be manufactured. For example, when manufacturing the sixth busbar 26, the portion that corresponds to the tuning fork terminal 40 is formed by a curved cutting line. In addition, holes may not be formed depending on the shape of the busbar 20.

Next, portions (enclosed by dashed-dotted lines) of the insulating member NP of the first molded body 52 are removed, so that a second molded body 53 is obtained (fourth step). With this, the connection portions 21E, 21F, and 21G are formed.

Finally, by folding the second molded body 53 at the fold line 54 indicated by a dashed-dotted line, the first busbar 21 (see FIG. 7) is obtained (fifth step). In the fifth step, the second molded body 53 is folded so that the bent edge BE of the first busbar 21 extends in the short side direction of the first busbar 21. The fold line 54 corresponds to the bent edge BE. By specifying the direction of the fold line 54 in this way, the bending processing of the second molded body 53 becomes easier. Also, the insulating member NP is less likely to be damaged at the bent edge BE. With this, the manufacturing of the first busbar 21 is completed.

The holding member 10 can be formed by injection molding or the like. As described above, the holding member 10 has housings for members, holes for engagement, and the like. The step of assembling members is performed by placing the members on the holding member 10 and connecting the members by bolting or the like. With this, the manufacturing of the electrical device 1 is complete.

### Functions and Effects of Embodiment 1

(1) The electrical device 1 according to Embodiment 1 includes heat generation components (the main relay 2, the precharge relay 3, and the precharge resistor 4), the busbar 20 connected to the heat generation components, and the holding member 10 that holds the heat generation components and the busbar 20, wherein the busbar 20 includes the conductor portion CP and the insulating member NP that has a radiation factor higher than that of the conductor portion CP and coats at least a part of the outer surface of the conductor portion CP.

According to this configuration, since at least a part of the outer surface of the conductor portion CP of the busbar 20 is coated with the insulating member NP, the insulation of the busbar 20 from the outside can be easily guaranteed. Also, since the insulating member NP has a radiation factor higher than that of the conductor portion CP, heat transferred from the heat generation components to the busbar 20 can be easily dissipated to the outside by radiation. In other words, heat dissipation from the heat generation component can be achieved easily. Accordingly, it is possible to dissipate heat from the heat generation component without increasing the size of the busbar 20.

(2) In Embodiment 1, a part of the busbar 20 is exposed to the outside.

With this configuration, it is possible to omit a member for externally covering the busbar 20.

(3) The electrical device 1 according to Embodiment 1 is the electrical device 1 mounted on the metal casing 6, and a part of the busbar 20 is in contact with the metal casing 6.

With this configuration, heat transferred from the heat generation component to the busbar 20 can be dissipated more easily.

### Embodiment 2

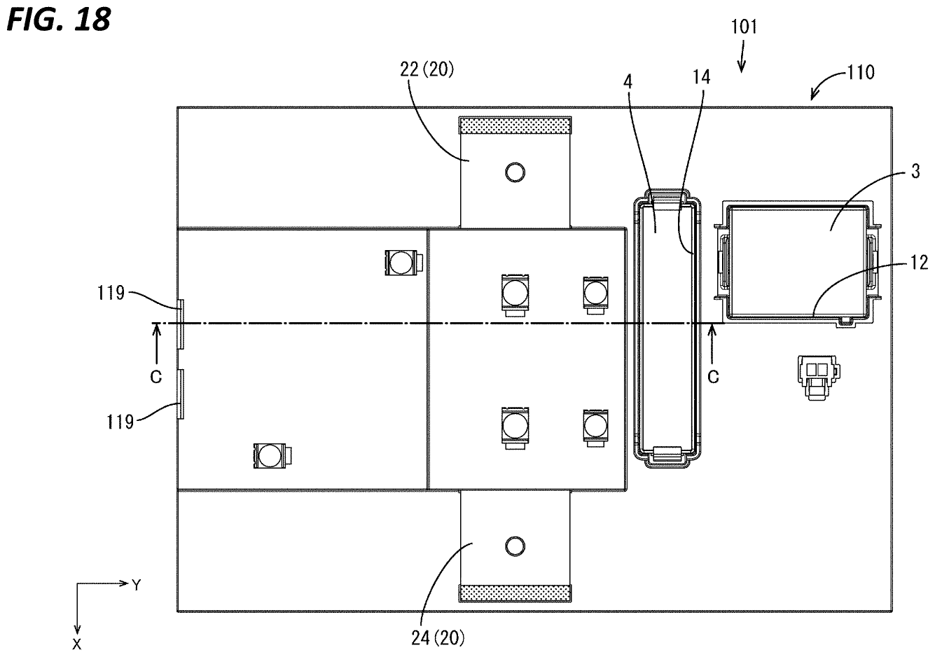

The following will describe Embodiment 2 of the present disclosure with reference to FIGS. 18 to 22. An electrical device 101 according to Embodiment 2 has substantially the same configuration as the electrical device 1 of Embodiment 1. Accordingly, in the following, the same reference signs are used for members that are essentially identical to those in Embodiment 1, and explanations may be omitted.

In Embodiment 2, the busbars 20 have substantially the same configuration as the busbars 20 of Embodiment 1, although the shape of the conductor portion CP, the range over which the insulating member NP is formed with respect to the conductor portion CP, the number of bent edges BE, and the like may be different from the busbars 20 of Embodiment 1.

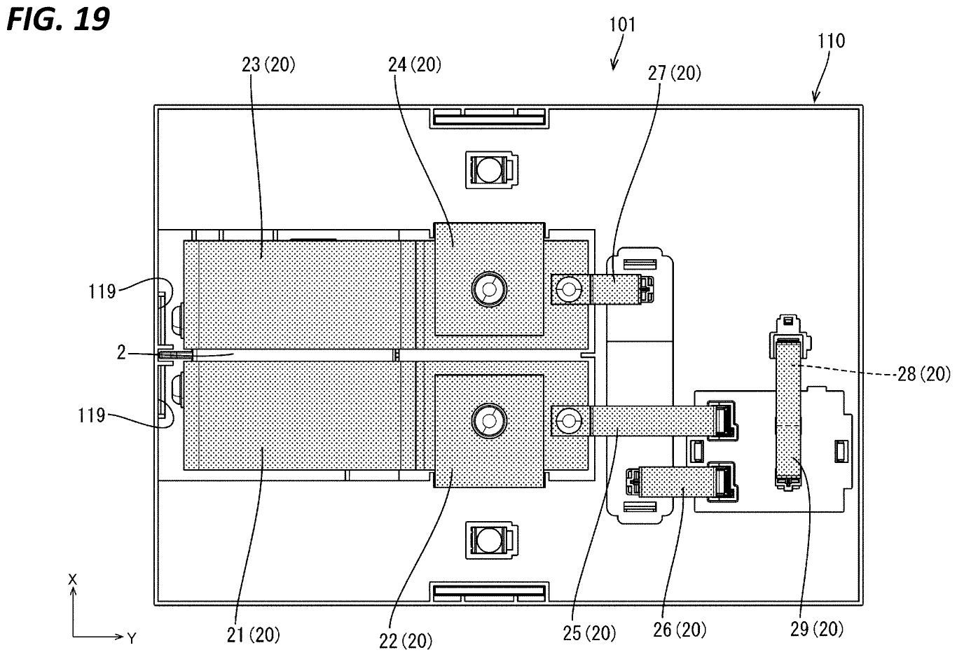

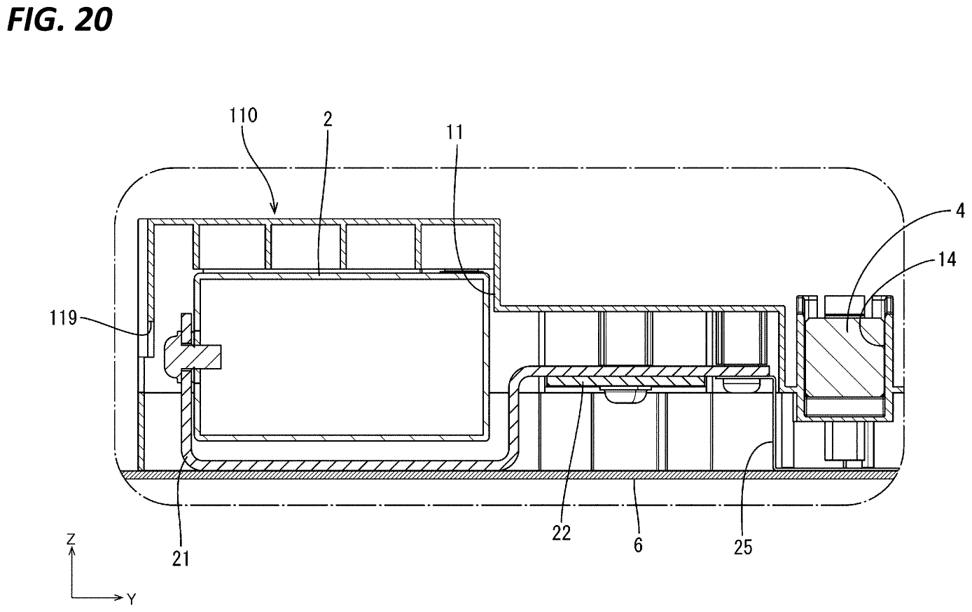

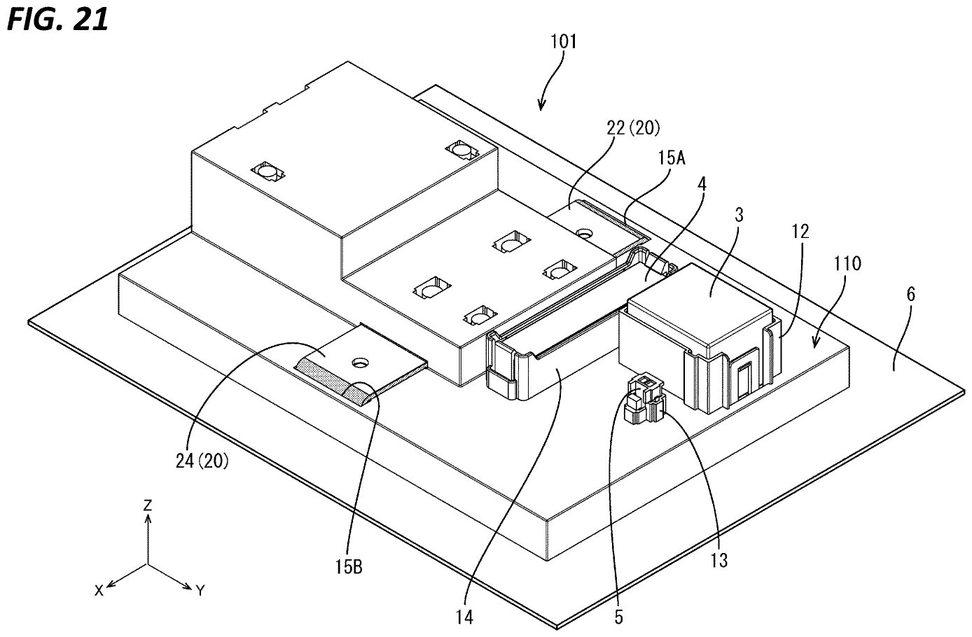

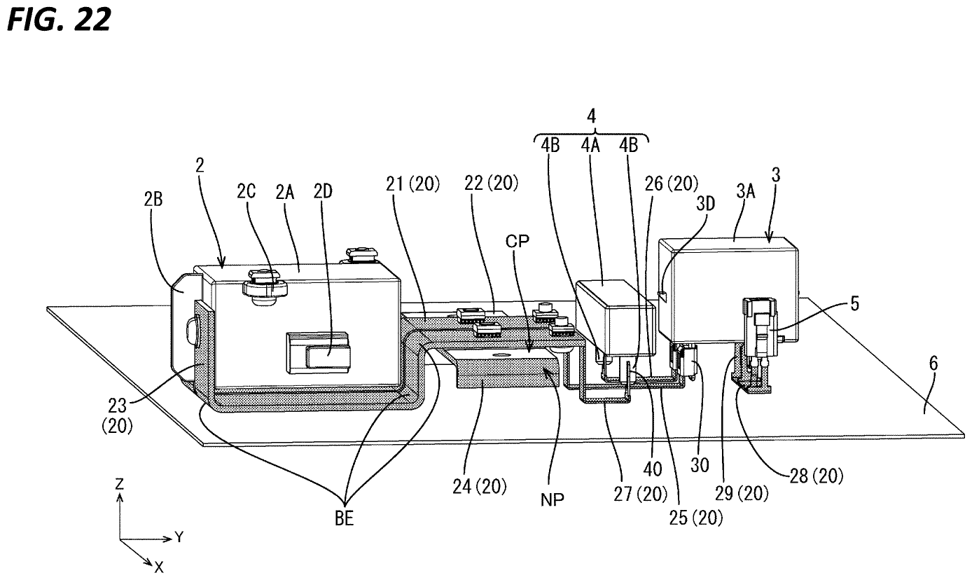

As shown in FIG. 19, a holding member 110 of Embodiment 2 differs from the holding member 10 of Embodiment 1 in that it holds the main relay 2, the first busbar 21, and the third busbar 23 on the underside of the holding member 110. The main relay 2, the first busbar 21, and the third busbar 23 are arranged inside the holding member 110 and are not exposed to the outside (see FIGS. 21 and 22). As shown in FIGS. 18 and 21, the precharge relay 3, the precharge resistor 4, the second busbar 22, and the fourth busbar 24 are held on the top side of the holding member 110. As shown in FIGS. 20 and 22, when the electrical device 101 is mounted on the metal casing 6, the first busbar 21 and the third busbar 23 are in contact with the metal casing 6. Therefore, in Embodiment 2, unlike Embodiment 1, heat transfer from the first busbar 21 and the third busbar 23 to the metal casing 6 is possible.

As shown in FIG. 20, the holding member 110 has a tool hole 119 that passes through the right wall of the holding member 110 in the left-right direction. A not-shown tool can be inserted into the tool hole 119, and the connection portion of the first busbar 21 and the terminal portion of the main relay 2 can be bolted from the outside. As shown in FIG. 19, a tool hole 119 for bolting the connection portion of the third busbar 23 and the terminal portion of the main relay 2 is also provided in the holding member 110.

The functions and effects of Embodiment 2 are substantially the same as the functions and effects of Embodiment 1, and explanations may be omitted.

### Other Embodiments

The above-described Embodiments 1 and 2 can be modified and implemented as follows. The above-described Embodiments 1 and 2 and the following modifications can be combined with each other and implemented as long as no technical contradiction arises.
In Embodiments 1 and 2 above, the main relay 2, the precharge relay 3, and the precharge resistor 4 were given as examples of heat generation components, but the heat generation components include any components that can generate heat upon being energized. The heat generation components may be, for example, resistors, coils, capacitors, fuses, diodes, ICs (Integrated Circuits), switching elements such as FETs (Field Effect Transistors), and the like.
In Embodiments 1 and 2 above, the electrical devices 1 and 101 were provided with nine busbars 20, but electrical devices need only be equipped with at least one busbar.
In Embodiments 1 and 2 above, the busbars 20 had a bent shape, but the shape of the busbars is not particularly limited. For example, the busbars may not be bent. Furthermore, if the busbars are bent, the direction in which the bent edges of the busbars extend may be set as appropriate.
In Embodiment 1 above, in the step of manufacturing the busbar 20, an extruder was used to coat the outer surface of conductor portion CP with the insulating member NP, but an insulating member may also be formed by, for example, electroplating or coating.

### LIST OF REFERENCE NUMERALS

1: Electrical device
2: Main relay
2A: Body portion
2B: Dividing wall
2C: Mounting piece
2D: Connector fitting portion
3: Precharge relay
3A: Body portion
3B: First terminal portion
3C: Second terminal portion
3D: Lock portion
4: Precharge resistor
4A: Body portion
4B: Terminal portion
5: Connector
6: Metal casing
10: Holding member
11: Main relay housing
11A: Nut mounting portion
12: Precharge relay housing
12A: Lock receiving portion
12B: First insertion hole
12C: Second insertion hole
13: Connector fitting portion
13A: Terminal hole
14: Precharge resistor housing
14A: Engagement portion
14B: Third insertion hole
15A, 15B: Busbar engagement hole
16: Nut mounting portion
17A, 17B, 17C, 17D: Mounting column
18: Busbar insertion hole
20: Busbar
21: First Busbar
21A: First portion
21B: Second portion
21C, 21D: Cut surface
21E: Connection portion
21E1: Through hole
21E2: Connection surface
21F: Connection portion
21F1: Through hole
21F2: Connection surface
21G: Connection portion
21G1: Through hole
21G2: Connection surface
22: Second busbar
22A: First portion
22B: Second portion
22C: Third portion
22D, 22E: Cut surface
22F: Connection portion
22F1: Through hole
22F2: Connection surface
22G: Connection portion
22G1: Through hole
22G2: Connection surface
23: Third busbar
24: Fourth busbar
24A: Connection portion
25: Fifth busbar
25A: First portion
25B: Second portion
25C: Third portion
25D: Cut surface
25E: Connection portion
25F: Connection portion
25F1: Through hole
25F2: Connection surface
26: Sixth busbar
26A: First portion
26B: Second portion
26C: Third portion
26D: Cut surface
26E: Connection portion
27: Seventh busbar
28: Eighth busbar
28A: First portion
28B: Second portion
28C: Third portion
28C1: Wide portion
28C2: Narrow portion
28D: Fourth portion
28E: Fifth portion
28F: Connection portion
28G: Cut surface
29: Ninth busbar
29A: First portion
29B: Second portion
29C: Third portion
29C1: Wide portion
29C2: Narrow portion
29D: Connection portion
29E: Cut surface
30: Intermediate terminal
31: Tubular connection portion
32: First contact portion
33: Second contact portion
40: Tuning fork terminal
41: Base
42: Pinching piece
43: Protrusion
50: Metal plate material
51: Coated plate material
52: First molded body
53: Second molded body
54: Fold line
101: Electrical device
B1: Mounting bolt
B2, B3, B4: Bolt
BE: Bent edge
BE1: First bent edge
BE2: Second bent edge
BE3: Third bent edge
BE4: Fourth bent edge
CP: Conductor portion
N1, N2, N3: Nut
NP: Insulating member

1. An electrical device comprising:
a heat generation component;
a busbar connected to the heat generation component; and
a holding member that holds the heat generation component and the busbar,
wherein the busbar has a conductor portion, and an insulating member that has a radiation factor higher than that of the conductor portion and coats at least a part of an outer surface of the conductor portion,
the electrical device has a plurality of the busbars, including a first busbar connected to the heat generation component and a second busbar connected to the first busbar, and
the first busbar is L-shaped when viewed in a first direction, and the second busbar has a first portion extending in the first direction and a second portion that extends in a second direction, which is orthogonal to the first direction, and is connected to an external connection busbar.

2. The electrical device according to claim 1,
wherein a part of the busbar is exposed to the outside.

3. The electrical device according to claim 1,
wherein the electrical device is mounted on a metal casing, and
a part of the busbar is in contact with the metal casing.
